(19) United States
(12) Patent Application Publication
(10) Pub. No.: US 2008/0096382 A1
(43) Pub. Date: Apr. 24, 2008

(54) METHOD FOR PRODUCING AN INTEGRATED CIRCUIT INCLUDING A CONNECTION CONTACT ON A SEMICONDUCTOR BODY

(75) Inventors: Paul GANITZER, Villach (AT); Walter RIEGER, Arnoldstein (AT); Martin POELZL, Ossiach (AT); Oliver HAEBERLEN, Villach (AT)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 11/873,685

(22) Filed: Oct. 17, 2007

(30) Foreign Application Priority Data
Oct. 19, 2006 (DE) 10 2006 049 354.0

(51) Int. Cl. H01L 21/4763

(52) U.S. Cl. 438/643; 257/E21.495

(57) ABSTRACT

A method for producing an integrated circuit is disclosed. One embodiment includes application of a barrier layer on the surface of the semiconductor body and in the trench, which barrier layer completely fills the trench and is at least partly deposited by using a CVD method. A metallization layer is produced onto a surface of the barrier layer that arose as a result of the application above the trench and the surface of the semiconductor body.

### CROSS-REFERENCE TO RELATED APPLICATIONS

This Utility Patent Application claims priority to German Patent Application No. DE 10 2006 049 354.0 filed on Oct. 19, 2006, which is incorporated herein by reference.

### BACKGROUND

The present invention relates to a method for producing a connection contact that makes contact with at least one semiconductor zone arranged adjacent to a trench in a semiconductor body.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a cross sectional view of and integrated circuit including a semiconductor body with a trench arranged therein prior to performing method processes according to an example.

FIG. 2 illustrates the semiconductor body after producing a barrier layer.

FIG. 3 illustrates the semiconductor body after applying a metallization layer on the barrier layer.

FIG. 4 illustrates the semiconductor body partially in cross section after applying a bonding wire to the metallization layer.

FIG. 5 illustrates the semiconductor body partially in cross section during a method process for patterning the metallization layer and the barrier layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

A method according to one embodiment provides for producing an integrated circuit including a connection contact for making contact with at least one semiconductor zone in a trench extending into a semiconductor body proceeding from a surface includes applying a barrier layer on the surface of the semiconductor body and in the trench, which barrier layer completely fills the trench, and producing of a metallization layer on a surface of the barrier layer that results from applying the barrier layer above the trench and the surface of the semiconductor body. The barrier layer is at least partly applied by using a CVD method.

In this method, in which the material of the barrier layer is used for filling the trench, cavity-free filling even of trenches having small dimensions or a large aspect ratio is possible since suitable materials for the barrier layer, such as e.g., tungsten, in contrast to suitable materials for the metallization layer, such as e.g., copper or aluminum, can completely fill even narrow cavities when applying of a CVD method for depositing them.

The barrier layer that is completely obtained in this method additionally provides for an increase in the mechanical loadability of the component since the materials used as barriers are mechanically harder than the materials of the metallization.

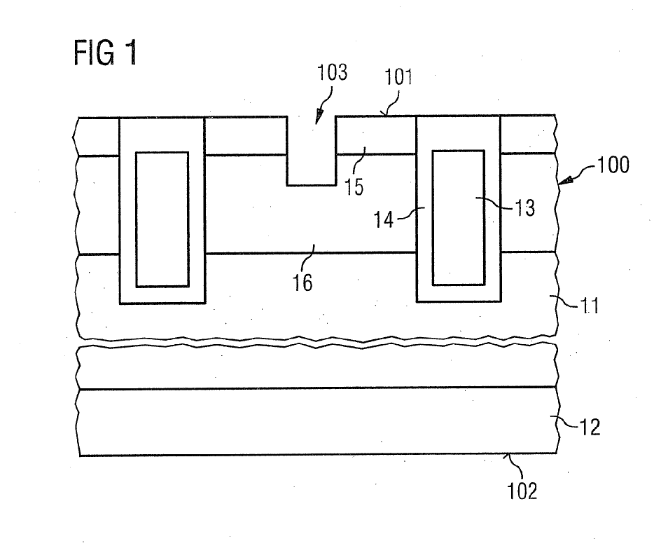

FIG. 1 illustrates partially a cross section through an integrated circuit including a semiconductor body 100 having a first surface 101, which is referred to hereinafter as front side, and a second surface 102 opposite the first surface 101, the second surface being referred to hereinafter as rear side. Proceeding from the front side 101, a trench 103 extends in a vertical direction into the semiconductor body, which has lateral areas and a bottom area. In the region of the trench, the semiconductor body 100 has two differently doped semiconductor zones 15, 16, which in the semiconductor body 100 adjoin the trench, i.e. adjoin the lateral areas thereof or the bottom area thereof.

In the example illustrated, the two semiconductor zones 15, 16 are the source zone 15 and the body zone 16 of a vertical power transistor structure. The power transistor structure includes, in addition to the source zone 15 arranged in the region of the front side 101 and the body zone 16 adjoining the source zone 15 in the vertical direction of the semiconductor body 100, a drift zone 11 adjoining the body zone 16 in the vertical direction, and a drain zone 12 adjoining the drift zone 11 in the vertical direction, the drain zone being arranged in the region of the rear side 102. In this case, the source zone 15 and the body zone 16 are doped complementarily with respect to one another. Furthermore, the body zone 16 is doped complementarily with respect to the drift zone 11. In the case of an n-conducting MOSFET, the source zone 15 and the drift zone 11 are n-doped and the body zone 16 is p-doped, and in the case of a p-conducting MOSFET, the component zones are p-doped and n-doped, respectively. The drain zone 12 is of the same conductivity type as the drift zone 11 in the case of a power transistor formed as a MOSFET, and is doped complementarily with respect to the drift zone 11 in the case of a power transistor formed as an IGBT.

A gate electrode 13 is present for controlling the power transistor, which gate electrode, in the example, is arranged in a trench extending into the semiconductor body in the vertical direction proceeding from the front size 101 and is dielectrically insulated from the semiconductor body 100 by using a gate dielectric 14. The gate electrode 13 extends in the vertical direction from the source zone 15 through the body zone 16 into the drift zone 11 and serves for controlling a conductive inversion channel along the gate dielectric 14 in the body zone 16. Contact can be made with the gate electrode 13 externally for applying a suitable gate potential in a manner that is not specifically illustrated. For this purpose, the gate electrode 13 may partially extend to the front side and be contact-connected there (not illustrated).

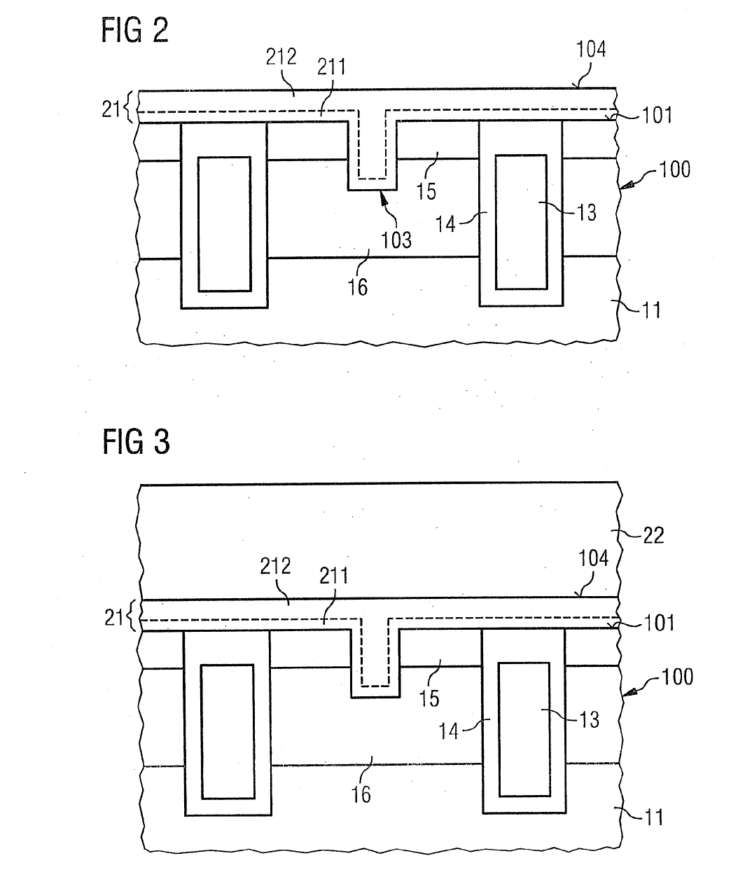

FIG. 2 illustrates the semiconductor body after first method processes have been carried out, which method processes involve producing a barrier layer 21 on the front side 101 of the semiconductor body 100 and in the trench 103. The barrier layer 21 is produced in such a way that the barrier layer 21 completely fills the trench 103. This can be achieved by the thickness of the barrier layer 21 applied to the front side 101 being greater than half of the width of the trench 103 in the lateral direction of the semiconductor body 100.

As is illustrated by dashed lines in FIG. 2, the barrier layer 21 can be produced by successively producing two or more partial layers 211, 212. FIG. 2 illustrates two such partial layers, of which a first partial layer 211 covers the front side 101 of the semiconductor body 100 and also the lateral areas and the bottom area of the trench 103, but does not completely fill the trench, such that a space remains after the production of the first partial layer 211 in the region of the trench 103. The subsequently produced second partial layer 212 of the barrier layer 21 covers the first partial layer 211 and completely fills the trench 103, or the cutout that remains after the production of the first partial layer 211.

The first partial layer 211 of the barrier layer is composed for example, of titanium (Ti) or titanium nitride (TiN) and is applied for example, by using a sputtering method. In this case, there is also the possibility of applying firstly a Ti layer as adhesion promoting layer and afterward a TiN layer, which together form the first partial layer 211.

The second partial layer 212 is a tungsten layer, for example, which is produced by using a CVD method (CVD=Chemical Vapor Deposition). In this case, the first partial layer 211 applied by sputtering serves as a “seed layer” for the deposition of the second partial layer 212 of the barrier layer 21.

A highly conductive carbon layer deposited by using a CVD method is additionally suitable as barrier layer 21.

The reference symbol 104 in FIG. 2 designates a surface of the barrier layer 21 that is uncovered after applying of the barrier layer. A metallization layer 22 is applied to the surface 104 directly, that is to say without prior etching back or grinding of the barrier layer 21. The result of this is illustrated in FIG. 3. The metallization layer 22 is for example an aluminum layer or a copper layer or includes an electrically conductive metal compound containing aluminum and/or copper.

In this example, the metallization layer 22 applied to the barrier layer 21 serves for applying an electrical potential to the semiconductor zones with which electrical contact is made through the barrier layer 21, in the example the source and body zones 15, 16 of the power transistor. It should be noted in this context that the power transistor has a multiplicity of transistor structures of identical type, transistor cells, which in each case have a connection contact arranged in a trench.

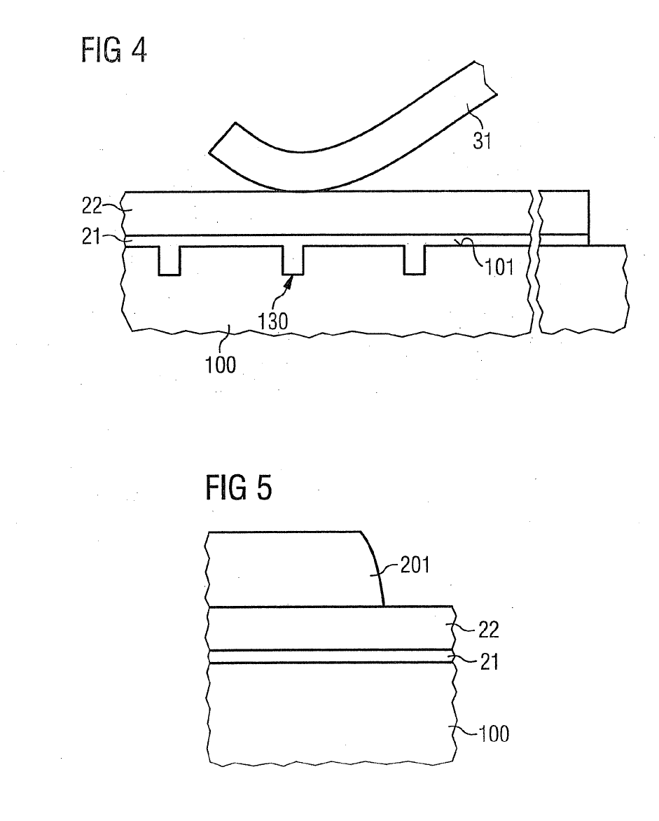

FIG. 4 illustrates a cross section through a semiconductor body 100 having a plurality of such trenches, with the remaining component zones are not illustrated in FIG. 4 for reasons of clarity.

In order to apply an electrical potential to the metallization layer 22, the metallization layer can be contact-connected by a connection line, for example, a bonding wire. FIG. 4 schematically illustrates such a bonding wire 31 applied to the metallization layer 22, which bonding wire can be applied to the metallization layer 22 by using a conventional method.

The barrier layer 21, which, when produced using the method, is arranged not only in the trenches 103 but also on the front side 101 of the semiconductor body. The barrier layer 21 is usually composed of a mechanically stronger material than the metallization layer 22, thereby protecting the semiconductor body 100 against mechanical loadings, for example those loadings which occur during the production of the bonding wire connection. Furthermore, the barrier layer 21 protects the semiconductor body 100 against contamination by indiffusing impurities. Such impurities may originate from a housing, for example, which is produced before finishing the manufacturing process by encapsulating the semiconductor body with a molding material by injection molding. Without the presence of a barrier layer, impurities from the housing could indiffuse into the semiconductor body 100 through the metallization layer 22.

As is schematically illustrated in the right-hand part of FIG. 4, the contact layer with the barrier layer 21 and the metallization layer 22 need not be applied to the front side 101 of the semiconductor body over the whole area, but rather can be patterned. A patterning of the contact layer with the barrier layer 21 and the metallization layer 22 can be effected, referring to FIG. 5, using a photomask applied to the metallization layer 22. In this case, the patterning can be effected in such a way that, in a first method process, the metallization layer 22 is etched using the photomask 201, that the photomask 201 is subsequently removed, and that, in a next process, the barrier layer 21 is patterned using the already patterned metallization layer 22 as a mask. The result is a contact layer which is illustrated by way of example in FIG. 4 and in which the barrier layer 21 is completely maintained below the metallization layer 22.

Instead of patterning the metallization layer 22 using a photomask, as an alternative there is the possibility of depositing the metallization layer in patterned fashion by using a “pattern plating” method. When this method is applied, a photomask is produced on the barrier layer and the metallization layer is deposited, by using a deposition method, only onto those regions of the barrier layer which are not covered by the photomask. After the removal of the photomask, the barrier layer can then likewise be patterned using the patterned metallization layer as a mask.

The method has been explained above on the basis of the production of a connection contact—specifically a source contact—for a power transistor. However, it goes without saying that the method is not restricted to the production of connection contacts for power transistors, but rather can be applied to the production of connection contacts arranged in trenches for any desired semiconductor components.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of making an integrated circuit including producing a connection contact for making contact with at least one semiconductor zone in a trench extending into a semiconductor body proceeding from a surface, the method comprising:
applying a barrier layer on the surface of the semiconductor body and in the trench, which barrier layer completely fills the trench and is at least partly deposited by using a CVD method; and
producing a metallization layer on a surface of the barrier layer, with the surface resulting from applying the barrier layer.

2. The method of claim 1, in which producing the barrier layer comprises producing a first partial layer and producing at least one second partial layer.

3. The method of claim 2, comprising wherein, after producing of the first partial layer, a space remains in the region of the trench, the space being filled by the second partial layer.

4. The method of claim 3, wherein the first partial layer comprises titanium and the second partial layer comprises tungsten.

5. The method of claim 4, comprising wherein the first partial layer is a titanium nitride layer.

6. The method of claim 1, comprising depositing the first partial layer by using a sputtering process and the second partial layer by using a CVD process.

7. The method of claim 1, wherein the metallization layer comprises aluminum or copper.

8. The method of claim 1, comprising wherein, in the semiconductor body, two semiconductor zones doped complementarily with respect to one another adjoin the trench.

9. The method of claim 8, comprising wherein the zones doped complementarily with respect to one another include a source zone and a body zone of a power MOS transistor.

10. The method of claim 9, further comprising:
patterning of the metallization layer in order to produce a patterned metallization layer; and
patterning of the barrier layer using the patterned metallization layer as a mask.

11. The method of claim 1, comprising:
depositing the metallization layer in patterned fashion; and
patterning the barrier layer using the patterned metallization layer as a mask.

12. A method for producing a semiconductor including a connection contact for making contact with at least one semiconductor zone in a trench extending into a semiconductor body proceeding from a surface, the method comprising:
applying a barrier layer on the surface of the semiconductor body and in the trench, which barrier layer completely fills the trench and is at least partly deposited by using a CVD method; and
producing a metallization layer on a surface of the barrier layer, with the surface resulting from applying the barrier layer.

13. The method of claim 12, in which producing the barrier layer comprises producing a first partial layer and producing at least one second partial layer.

14. The method of claim 13, comprising wherein, after producing of the first partial layer, a space remains in the region of the trench, the space being filled by the second partial layer.

15. The method of claim 14, wherein the first partial layer comprises titanium and the second partial layer comprises tungsten.

16. The method of claim 15, comprising wherein the first partial layer is a titanium nitride layer.

17. The method of claim 12, comprising depositing the first partial layer by using a sputtering process and the second partial layer by using a CVD process.

18. The method of claim 12, wherein the metallization layer comprises aluminum or copper.

19. The method of claim 12, comprising wherein, in the semiconductor body, two semiconductor zones doped complementarily with respect to one another adjoin the trench.

20. The method of claim 19, comprising wherein the zones doped complementarily with respect to one another include a source zone and a body zone of a power MOS transistor.

21. The method of claim 20, further comprising:
patterning of the metallization layer in order to produce a patterned metallization layer; and
patterning of the barrier layer using the patterned metallization layer as a mask.

22. The method of claim 12, comprising:
depositing the metallization layer in patterned fashion; and
patterning the barrier layer using the patterned metallization layer as a mask.

23. A method for producing a semiconductor including a connection contact for making contact with at least one semiconductor zone in a trench extending into a semiconductor body proceeding from a surface, the method comprising:
applying a barrier layer on the surface of the semiconductor body and in the trench, which barrier layer completely fills the trench and is at least partly deposited by using a CVD method;
producing a metallization layer on a surface of the barrier layer, with the surface resulting from applying the barrier layer; and
forming a transistor in the semiconductor body, contacting the metallization layer.
